(19) United States
(12) Patent Application Publication
(10) Pub. No.: US 2019/0067610 A1
(43) Pub. Date: Feb. 28, 2019

(54) PASSIVATED THIN FILM TRANSISTOR COMPONENT

(71) Applicant: Dow Global Technologies LLC, Midland, MI (US)

(72) Inventors: Xiaomei SONG, Shanghai (CN); Yuanqiao RAO, Freeport, TX (US); Nan HU, Shanghai (CN); Zhe LI, Shanghai (CN); Andong LIU, Shanghai (CN); Wen YANG, Shanghai (CN); Jianping XU, Shanghai (CN)

(21) Appl. No.: 16/070,788

(22) PCT Filed: Mar. 31, 2016
(86) PCT No.: PCT/CN2016/077998

§ 371 Date: Jul. 18, 2018

(51) Int. Cl. H01L 51/10; H01L 23/31; H01L 23/29; H01L 29/786

(52) U.S. Cl. CPC H01L 51/107; H01L 23/3171; H01L 27/1248; H01L 23/295; H01L 29/78606; H01L 23/296

(57) ABSTRACT

A method of making a passivated thin film transistor component for use in a display device, is provided, comprising: providing a thin film transistor component, comprising: a substrate, at least one electrode, a dielectric and a semiconductor; providing a film forming matrix material; and, providing a plurality of non-crystalline hydrophobic silica particles having an average particle size of 5 to 120 nm and a water absorbance of <2% determined according to ASTM E1131; combining the film forming matrix material and the plurality of non-crystalline hydrophobic silica particles to form a composite; and, applying the composite to the thin film transistor component to form a barrier film thereon, providing the passivated thin film transistor component; wherein the semiconductor is interposed between the barrier film and the substrate.

The invention relates to the field of passivated thin film transistor components for use in optical displays. In particular, the invention relates to a method of making a passivated thin film transistor component for use in a display device, which comprises: providing a thin film transistor component, comprising: a substrate, at least one electrode, a dielectric and a semiconductor; providing a film forming matrix material; and, providing a plurality of non-crystalline hydrophobic silica particles having an average particle size, PS_{avg}, of 5 to 120 nm and a water absorbance of <2% determined according to ASTM E1131; combining the film forming matrix material and the plurality of non-crystalline hydrophobic silica particles to form a composite; and, applying the composite to the thin film transistor component to form a barrier film thereon, providing the passivated thin film transistor component; wherein the semiconductor is interposed between the barrier film and the substrate.

Liquid crystal displays (LCDs) have been employed in ever increasing numbers since their initial development by RCA back in 1968 in a wide variety of optical devices. Given that they do not emit any light directly, LCDs are integrated with a light source to form the optical device. In more recent device designs, LCDs are integrated with light emitting diodes (LEDs) or organic light emitting diodes (OLEDs) as the light source.

A particular variant of LCD, is a thin film transistor liquid crystal display (TFT LCD). TET LCDs are used in a wide variety of optical display devices including, computer monitors, televisions, mobile phone displays, hand held video games, personal digital assistants, navigation tools, display projectors, and electronic instrument clusters.

Thin film transistors (TFTs) are fundamental building blocks of electronic circuits that are used in, for example, both light crystal display (LCD) and organic light emitting diode (OLED) type devices. Structurally, TFTs typically comprise a supporting substrate, a gate electrode, a source electrode, a drain electrode, a semiconductor layer and a dielectric layer. Exposure to various environmental elements can negatively impact the performance of TFTs. In particular, the semiconductor layers in TFTs have transient conductivity determined by an applied gate voltage. The charge transport properties of the incorporated semiconductor layers in TFTs typically exhibit deterioration upon exposure to moisture and oxygen during use. Consequently for operational stability and extended life, TFTs require protection from such environmental elements provided through incorporation of protective barrier or encapsulation layer(s).

Incumbent TFT passivation materials (e.g., SiNₓ) are deposited using plasma enhanced chemical vapor deposition (PECVD) processing techniques. Such PECVD techniques require significant capital investment and multiple processing steps. Alternative, lower cost passivation materials and solution processed thin film passivation coatings to TFTs in both LCD and OLED display applications would be desirable to lower manufacturing costs.

One solution processed thin film passivation coating approach is disclosed by Birau et al. in U.S. Pat. No. 7,705,346. Birau et al. disclose an organic thin film transistor comprising a substrate, a gate electrode, a semiconductor layer, and a barrier layer; wherein the gate electrode and the semiconductor layer are located between the substrate and the barrier layer; wherein the substrate is a first outermost layer of the transistor and the barrier layer is a second outermost layer of the transistor; and wherein the barrier layer comprises a polymer, an antioxidant, and a surface modified inorganic particulate material.

Notwithstanding, there remains a need for alternative barrier layer compositions and manufacturing methods for use in TFT LCDs, particularly TFT LCDs that incorporate LED or OLED type light sources.

The present invention provides a method of making a passivated thin film transistor component for use in a display device, comprising: providing a thin film transistor component, comprising: a substrate, at least one electrode, a dielectric and a semiconductor; providing a film forming matrix material; and, providing a plurality of non-crystalline hydrophobic silica particles having an average particle size, PS_{avg}, of 5 to 120 nm and a water absorbance of <2% determined according to ASTM E1131, wherein the plurality of non-crystalline hydrophobic silica particles are prepared by: providing a plurality of hydrophilic silica particles; providing a water; providing an aldose; dispersing the plurality of hydrophilic silica particles in the water to form a silica water dispersion; dissolving the aldose in the silica water dispersion to form a combination; concentrating the combination to form a viscous syrup; heating the viscous syrup in an inert atmosphere at 500 to 625° C. for 4 to 6 hours to form a char; comminuting the char to form a powder; heating the powder in an oxygen containing atmosphere at >650 to 900° C. for 1 to 2 hours to form the plurality of non-crystalline hydrophobic silica particles; combining the film forming matrix material and the plurality of non-crystalline hydrophobic silica particles to form a composite; and, applying the composite to the thin film transistor component to form a barrier film thereon, providing the passivated thin film transistor component; wherein the semiconductor is interposed between the barrier film and the substrate; wherein the barrier film has a water vapor transmission rate of ≤10.0 g·mil/m²·day measured at 38° C. and 100% relative humidity according to ASTM F1249.

The present invention provides a method of making a passivated thin film transistor component for use in a display device, comprising: providing a thin film transistor component, comprising: a substrate, at least one electrode, a dielectric and a semiconductor; providing a film forming matrix material; and, providing a plurality of non-crystalline hydrophobic silica particles having an average particle size, PS_{avg}, of 5 to 120 nm; an average aspect ratio, AR_{avg}, of ≤1.5 and a polydispersity index, PdI, of ≤0.275 determined by dynamic light scattering according to ISO 22412:2008; and, a water absorbance of <2% determined according to ASTM E1131, wherein the plurality of non-crystalline hydrophobic silica particles are prepared by: providing a plurality of hydrophilic silica particles; providing a water; providing an aldose; dispersing the plurality of hydrophilic silica particles in the water to form a silica water dispersion; dissolving the aldose in the silica water dispersion to form a combination; concentrating the combination to form a viscous syrup; heating the viscous syrup in an inert atmosphere at 500 to 625° C. for 4 to 6 hours to form a char; comminuting the char to form a powder; heating the powder in an oxygen containing atmosphere at >650 to 900° C. for 1 to 2 hours to form the plurality of non-crystalline hydrophobic silica particles; combining the film forming matrix material and the plurality of non-crystalline hydrophobic silica particles to form a composite; and, applying the composite to the thin film transistor component to form a barrier film thereon, providing the passivated thin film transistor component; wherein the semiconductor is interposed between the barrier film and the substrate; wherein the barrier film has a water vapor transmission rate of ≤10.0 g·mil/m²·day measured at 38° C. and 100% relative humidity according to ASTM F1249.

The present invention provides a method of making a passivated thin film transistor component for use in a display device, comprising: providing a thin film transistor component, comprising: a substrate, at least one electrode, a dielectric and a semiconductor; providing a film forming matrix material, wherein the film forming matrix material provided is a polysiloxane; and, providing a plurality of non-crystalline hydrophobic silica particles having an average particle size, PS_{avg}, of 5 to 120 nm and a water absorbance of <2% determined according to ASTM E1131, wherein the plurality of non-crystalline hydrophobic silica particles are prepared by: providing a plurality of hydrophilic silica particles; providing a water; providing an aldose; dispersing the plurality of hydrophilic silica particles in the water to form a silica water dispersion; dissolving the aldose in the silica water dispersion to form a combination; concentrating the combination to form a viscous syrup; heating the viscous syrup in an inert atmosphere at 500 to 625° C. for 4 to 6 hours to form a char; comminuting the char to form a powder; heating the powder in an oxygen containing atmosphere at >650 to 900° C. for 1 to 2 hours to form the plurality of non-crystalline hydrophobic silica particles; combining the film forming matrix material and the plurality of non-crystalline hydrophobic silica particles to form a composite; and, applying the composite to the thin film transistor component to form a barrier film thereon, providing the passivated thin film transistor component; wherein the semiconductor is interposed between the barrier film and the substrate; wherein the barrier film has a water vapor transmission rate of ≤10.0 g·mil/m²·day measured at 38° C. and 100% relative humidity according to ASTM F1249.

The present invention provides a method of making a passivated thin film transistor component for use in a display device, comprising: providing a thin film transistor component, comprising: a substrate, at least one electrode, a dielectric and a semiconductor; providing a film forming matrix material, wherein the film forming matrix material provided is a polysiloxane, wherein the polysiloxane provided has an average compositional formula:

(R³SiO_{3/2})ₐ(SiO_{4/2})_{b}

wherein each R³ is independently selected from a C₆₋₁₀ aryl group and a C₇₋₂₀ alkylaryl group; wherein each R⁷ and R⁹ is independently selected from a hydrogen atom, a C₁₋₁₀ alkyl group, a C₇₋₁₀ arylalkyl group, a C₇₋₁₀ alkylaryl group and a C₆₋₁₀ aryl group; wherein 0≤a≤0.5; wherein 0.5≤b≤1; wherein a+b=1; wherein the polysiloxane comprises, as initial components: (i) T units having a formula R³Si(OR₇)₃; and, (ii) Q units having a formula Si(OR⁹)₄; and, providing a plurality of non-crystalline hydrophobic silica particles having an average particle size, PS_{avg}, of 5 to 120 nm and a water absorbance of <2% determined according to ASTM E1131, wherein the plurality of non-crystalline hydrophobic silica particles are prepared by: providing a plurality of hydrophilic silica particles; providing a water; providing an aldose; dispersing the plurality of hydrophilic silica particles in the water to form a silica water dispersion; dissolving the aldose in the silica water dispersion to form a combination; concentrating the combination to form a viscous syrup; heating the viscous syrup in an inert atmosphere at 500 to 625° C. for 4 to 6 hours to form a char; comminuting the char to form a powder; heating the powder in an oxygen containing atmosphere at >650 to 900° C. for 1 to 2 hours to form the plurality of non-crystalline hydrophobic silica particles; combining the film forming matrix material and the plurality of non-crystalline hydrophobic silica particles to form a composite; and, applying the composite to the thin film transistor component to form a barrier film thereon, providing the passivated thin film transistor component; wherein the semiconductor is interposed between the barrier film and the substrate; wherein the barrier film has a water vapor transmission rate of ≤10.0 g·mil/m²·day measured at 38° C. and 100% relative humidity according to ASTM F1249.

The present invention provides a method of making a passivated thin film transistor component for use in a display device, comprising: providing a thin film transistor component, comprising: a substrate, at least one electrode, a dielectric and a semiconductor; providing a film forming matrix material; providing an organic solvent; and, providing a plurality of non-crystalline hydrophobic silica particles having an average particle size, PS_{avg}, of 5 to 120 nm and a water absorbance of <2% determined according to ASTM E1131, wherein the plurality of non-crystalline hydrophobic silica particles are prepared by: providing a plurality of hydrophilic silica particles; providing a water; providing an aldose; dispersing the plurality of hydrophilic silica particles in the water to form a silica water dispersion; dissolving the aldose in the silica water dispersion to form a combination; concentrating the combination to form a viscous syrup; heating the viscous syrup in an inert atmosphere at 500 to 625° C. for 4 to 6 hours to form a char; comminuting the char to form a powder; heating the powder in an oxygen containing atmosphere at >650 to 900° C. for 1 to 2 hours to form the plurality of non-crystalline hydrophobic silica particles; combining the film forming matrix material, the organic solvent and the plurality of non-crystalline hydrophobic silica particles to form a composite; and, applying the composite to the thin film transistor component to form a barrier film thereon, providing the passivated thin film transistor component; wherein the semiconductor is interposed between the barrier film and the substrate; wherein the barrier film has a water vapor transmission rate of ≤10.0 g·mil/m²·day measured at 38° C. and 100% relative humidity according to ASTM F1249.

The present invention provides a method of making a passivated thin film transistor component for use in a display device, comprising: providing a thin film transistor component, comprising: a substrate, at least one electrode, a dielectric and a semiconductor; providing a film forming matrix material; providing an additive; and, providing a plurality of non-crystalline hydrophobic silica particles having an average particle size, PS_{avg}, of 5 to 120 nm and a water absorbance of <2% determined according to ASTM E1131, wherein the plurality of non-crystalline hydrophobic silica particles are prepared by: providing a plurality of hydrophilic silica particles; providing a water; providing an aldose; dispersing the plurality of hydrophilic silica particles in the water to form a silica water dispersion; dissolving the aldose in the silica water dispersion to form a combination; concentrating the combination to form a viscous syrup; heating the viscous syrup in an inert atmosphere at 500 to 625° C. for 4 to 6 hours to form a char; comminuting the char to form a powder; heating the powder in an oxygen containing atmosphere at >650 to 900° C. for 1 to 2 hours to form the plurality of non-crystalline hydrophobic silica particles; combining the film forming matrix material, the additive and the plurality of non-crystalline hydrophobic silica particles to form a composite; and, applying the composite to the thin film transistor component to form a barrier film thereon, providing the passivated thin film transistor component; wherein the semiconductor is interposed between the barrier film and the substrate; wherein the barrier film has a water vapor transmission rate of ≤10.0 g·mil/m²·day measured at 38° C. and 100% relative humidity according to ASTM F1249.

The present invention provides a passivated thin film transistor component for use in a display device made according to the method of the present invention.

### BRIEF DESCRIPTION OF THE DRAWINGS

FIG. 1 is a depiction side elevational view of a passivated thin film transistor component in accordance with the present invention.

FIG. 2 is a depiction side elevational view of a passivated thin film transistor component in accordance with the present invention.

FIG. 3 is a depiction side elevational view of a passivated thin film transistor component in accordance with the present invention.

FIG. 4 is a depiction side elevational view of a passivated thin film transistor component in accordance with the present invention.

### DETAILED DESCRIPTION

Passivated thin film transistor components designed for use in a display devices of the present invention incorporate a barrier layer that includes a plurality of non-crystalline hydrophobic silica particles having a low average aspect ratio and a narrow particle size, PS_{avg}, distribution prepared from a plurality of hydrophilic silica particles (e.g., Stöber silica particles), wherein the plurality of hydrophilic silica particles have a particle size of <120 nm, a low average aspect ratio, AR_{avg}, and a low polydispersity index, PdI, which are retained during the formation of the plurality of non-crystalline hydrophobic silica particles therefrom. That is, the unique process of the invention enables the formation of the plurality of non-crystalline hydrophobic silica particles from the plurality of hydrophilic silica particles while avoiding agglomeration and while retaining a low average aspect ratio, AR_{avg}, and a low polydispersity index, PdI.

Preferably, the method of making a passivated thin film transistor component for use in a display device of the present invention, comprises: providing a thin film transistor component, comprising: a substrate, at least one electrode, a dielectric and a semiconductor; providing a film forming matrix material; and, providing a plurality of non-crystalline hydrophobic silica particles having an average particle size of 5 to 120 nm (preferably, 10 to 110 nm; more preferably, 20 to 100 nm; most preferably, 25 to 90 nm) (wherein the particle size is measured using well known low angle laser light scattering laser diffraction) and a water absorbance of <2% determined according to ASTM E1131, wherein the plurality of non-crystalline hydrophobic silica particles are prepared by: providing a plurality of hydrophilic silica particles (preferably, wherein the plurality of hydrophilic silica particles provided are prepared using a Stober synthesis process); providing a water; providing an aldose (preferably, wherein the aldose provided is an aldohexose; more preferably, wherein the aldose is an aldohexose selected from the group consisting of D-allose, D-altrose, D-glucose, D-mannose, D-gulose, D-idose, D-galactose, D-talose; still more preferably, wherein the aldose is an aldohexose selected from D-glucose, D-galactose and D-mannose; most preferably, wherein the aldose is D-glucose); dispersing the plurality of hydrophilic silica particles in the water to form a silica water dispersion; dissolving the aldose in the silica water dispersion to form a combination; concentrating the combination to form a viscous syrup; heating the viscous syrup in an inert atmosphere at 500 to 625° C. for 4 to 6 hours to form a char; comminuting the char to form a powder (preferably, comminuting the char by at least one of crushing, pulverizing and grinding to form a powder); heating the powder in an oxygen containing atmosphere at >650 to 900° C. for 1 to 2 hours to form the plurality of non-crystalline hydrophobic silica particles; combining the film forming matrix material and the plurality of non-crystalline hydrophobic silica particles to form a composite; and, applying the composite to the thin film transistor component to form a barrier film (preferably, a transparent barrier film; more preferably, wherein the barrier film is a transparent barrier film and wherein the barrier film has a transmission, T_{Trans}, of ≥50% (still more preferably T_{Trans} is ≥80%; most preferably, T_{Trans} ≥90%) as measured according to ASTM D1003-11e1); thereon, providing the passivated thin film transistor component; wherein the semiconductor is interposed between the barrier film and the substrate; wherein the barrier film has a water vapor transmission rate of ≤10.0 g·mil/m²·day (preferably, <10 g·mil/m²·day; more preferably, ≤7.5 g·mil/m²·day; most preferably, ≤5.0 g·mil/m²·day) measured at 38° C. and 100% relative humidity according to ASTM F1249.

Preferably, in the method of making a passivated thin film transistor component for use in a display device of the present invention, the thin film transistor component provided, comprises: a substrate, at leak one electrode, a dielectric and a semiconductor. More preferably, in the method of making a passivated thin film transistor component for use in a display device of the present invention, the thin film transistor component provided, comprises: a substrate, a source electrode, a drain electrode, a dielectric and a semiconductor; wherein the substrate also functions as a gate electrode. Most preferably, in the method of making a passivated thin film transistor component for use in a display device of the present invention, the thin film transistor component provided, comprises: a substrate, a source electrode, a gate electrode, a drain electrode, a dielectric and a semiconductor.

In the method of making a passivated thin film transistor component for use in a display device of the present invention, one of ordinary skill in the art will be able to select appropriate materials for use as the substrate of the thin film transistor component provided. Preferably, in the method of making a passivated thin film transistor component for use in a display device of the present invention, the substrate of the thin film transistor component provided can be opaque or transparent provided that the substrate exhibits the requisite mechanical properties for the given display application. More preferably, in the method of making a passivated thin film transistor component for use in a display device of the present invention, the substrate of the thin film transistor component provided is selected from the group consisting of silicon substrates (e.g., a silicon wafer); glass substrates and plastic substrates. Still more preferably, in the method of making a passivated thin film transistor component for use in a display device of the present invention, the substrate of the thin film transistor component provided is a plastic substrate selected from the group consisting of a polyester substrate, a polycarbonate substrate and a polyimide substrate.

Preferably, in the method of making a passivated thin film transistor component for use in a display device of the present invention, the substrate of the thin film transistor component provided can provide dual functionality acting as both a substrate and as a gate electrode. More preferably, in the method of making a passivated thin film transistor component for use in a display device of the present invention, the substrate of the thin film transistor component provided is selected from doped silicon oxide substrates. Preferably, in the method of making a passivated thin film transistor component for use in a display device of the present invention, the substrate of the thin film transistor component provided is a heavily n-doped silicon wafer, which functions as both a substrate and as a gate electrode.

In the method of making a passivated thin film transistor component for use in a display device of the present invention, one of ordinary skill in the art will be able to select appropriate materials for use as the at least one electrode of the thin film transistor component provided. Preferably, in the method of making a passivated thin film transistor component for use in a display device of the present invention, the at least one electrode of the thin film transistor component provided is an electrically conductive material. More preferably, in the method of making a passivated thin film transistor component for use in a display device of the present invention, the at least one electrode of the thin film transistor component provided is selected from the group consisting of metals, conductive polymers, conductive metal alloys and conductive ceramics. Still more preferably, in the method of making a passivated thin film transistor component for use in a display device of the present invention, the at least one electrode of the thin film transistor component provided is selected from the group consisting of aluminum, gold, chromium, copper, tungsten, silver, indium tin oxide, polystyrene sulfonate doped poly(3,4-ethylenedioxythiophene) (PSS-PEDOT), carbon nanotubes, carbon black, graphite and graphene.

In the method of making a passivated thin film transistor component for use in a display device of the present invention, one of ordinary skill in the art will be able to select appropriate materials for use as the semiconductor of the thin film transistor component provided. Preferably, in the method of making a passivated thin film transistor component for use in a display device of the present invention, semiconductor of the thin film transistor component provided is selected from oxides (e.g., SnO₂, ZnO); sulfides (e.g., polycrystalline CdS); silicon (e.g., amorphous silicon, low temperature polycrystalline silicon) and organic semiconductors. More preferably, in the method of making a passivated thin film transistor component for use in a display device of the present invention, the semiconductor of the thin film transistor component provided is an organic semiconductor selected from the group consisting of anthracene, tetracene, pentacene, perylenes, fullerenes, phthalocyanines, oligothiophenes, polythiophenes and derivatives thereof.

In the method of making a passivated thin film transistor component for use in a display device of the present invention, one of ordinary skill in the art will be able to select appropriate materials for use as the dielectric of the thin film transistor component provided. Preferably, in the method of making a passivated thin film transistor component for use in a display device of the present invention, the dielectric of the thin film transistor component provided is selected from inorganic dielectrics (e.g., silicon oxide, silicon nitride, aluminum oxide, barium titanate, barium zirconate titanate), organic dielectrics e.g., polyesters, polycarbonates, polyvinyl phenol), polyimides, polystyrene, poly(alkyl)acrylates, epoxies) and composites thereof (e.g., polymers containing metal oxide particle filler).

Preferably, in the method of making a passivated thin film transistor component for use in a display device of the present invention, the film forming matrix material provided is selected from the group consisting of a paraffin wax, a polyolefin, a poly(alkyl)acrylate, a polyimide, a polyester, a polysulfone, a poly ether ketone, a polycarbonate, a polysiloxane and mixtures thereof. More preferably, in the method of making a passivated thin film transistor component for use in a display device of the present invention, the film forming matrix material provided is a polysiloxane. Still more preferably, in the method of making a passivated thin film transistor component for use in a display device of the present invention, the film forming matrix material provided is a polysiloxane formed from a combination of a tetraalkylorthosilicate and a phenyltrialkoxysilane. Most preferably in the method of making a passivated thin film transistor component for use in a display device of the present invention, the film forming matrix material provided is a polysiloxane formed from a combination of a tetraethylorthosilicate and a phenyltrimethoxysilane.

Preferably, in the method of making a passivated thin film transistor component for use in a display device of the present invention, the film forming matrix material provided is a polysiloxane having an average compositional formula:

(R³ₓSiO_{((4-x)/2)})ₐ(SiO_{4/2})_{b}

wherein each R³ is independently selected from a C₆₋₁₀ aryl group and a C₇₋₂₀ alkylaryl group; wherein x is 1 to 3; wherein 0≤a≤0.5 (preferably, 0.05 to 0.25; more preferably, 0.075 to 0.2; most preferably, 0.09 to 0.15); wherein 0.5≤b≤1 (preferably, 0.75 to 0.99; more preferably, 0.8 to 0.975; most preferably, 0.85 to 0.92); wherein a+b=1. More preferably, in the method of making a passivated thin film transistor component for use in a display device of the present invention, the film forming matrix material provided is a polysiloxane having an average compositional formula:

(R³SiO_{3/2})ₐ(SiO_{4/2})_{b}

wherein each R³ is independently selected from a C₆₋₁₀ aryl group and a C₇₋₂₀ alkylaryl group; wherein 0≤a≤0.5 (preferably, 0.05 to 0.25; more preferably, 0.075 to 0.2; most preferably, 0.09 to 0.15); wherein 0.5≤b≤1 (preferably, 0.75 to 0.99; more preferably, 0.8 to 0.975; most preferably, 0.85 to 0.92); wherein a+b=1. Still more preferably, in the method of making a passivated thin film transistor component for use in a display device of the present invention, the film forming matrix material provided is a polysiloxane having an average compositional formula:

(R³SiO_{3/2})ₐ(SiO_{4/2})_{b}

wherein each R³ is independently selected from a C₆₋₁₀ aryl group and a C₇₋₂₀ alkylaryl group; wherein 0≤a≤0.5 (preferably, 0.05 to 0.25; more preferably, 0.075 to 0.2; most preferably, 0.09 to 0.15); wherein 0.5≤b≤1 (preferably, 0.75 to 0.99; more preferably, 0.8 to 0.975; most preferably, 0.85 to 0.92); wherein a+b=1; wherein the polysiloxane comprises, as initial components: (i) T units having a formula R³Si(OR⁷)₃; and, (ii) Q units having a formula Si(OR⁹)₄; wherein each R⁷ and R⁹ is independently selected from a hydrogen atom, a C₁₋₁₀ alkyl group, a C₇₋₁₀ arylalkyl group, a C₇₋₁₀ alkylaryl group and a C₆₋₁₀ aryl group. Still more preferably, in the method of making a passivated thin film transistor component for use in a display device of the present invention, the film forming matrix material provided is a polysiloxane having an average compositional formula:

(R³SiO_{3/2})ₐ(SiO_{4/2})_{b}

wherein each R³ is a C₆ aryl group; wherein 0≤a≤0.5 (preferably, 0.05 to 0.25; more preferably, 0.075 to 0.2; most preferably, 0.09 to 0.15); wherein 0.5≤b≤1 (preferably, 0.75 to 0.99; more preferably, 0.8 to 0.975; most preferably, 0.85 to 0.92); wherein a+b=1; wherein the polysiloxane comprises, as initial components: (i) T units having a formula R³Si(OR⁷)₃; and, (ii) Q units having a formula. Si(OR⁹)₄; wherein each R⁷ is a C₁ alkyl group; and wherein each R⁹ is a C₂ alkyl group.

Preferably, in the method of making a passivated thin film transistor component for use in a display device of the present invention, the plurality of non-crystalline hydrophobic silica particles provided have an average particle size, PS_{avg}, of 5 to 120 nm (preferably, 10 to 110 nm; more preferably, 20 to 100 nm; most preferably, 25 to 90 nm) wherein the particle size is measured using well known low angle laser light scattering laser diffraction and a water absorbance of <2% determined according to ASTM E1131. More preferably, in the method of making a passivated thin film transistor component for use in a display device of the present invention, the plurality of non-crystalline hydrophobic silica particles provided have an average particle size of 5 to 120 nm (preferably, 10 to 110 nm; more preferably, 20 to 100 nm; most preferably, 25 to 90 nm) and a polydispersity index, PdI, of ≤0.275 (preferably, 0.05 to 0.275; more preferably, of 0.1 to 0.25; most preferably, 0.15 to 0.2) determined by dynamic light scattering according to ISO 22412:2008; and a water absorbance of <2% determined according to ASTM E1131.

Preferably, in the method of making a passivated thin film transistor component for use in a display device of the present invention, the plurality of non-crystalline hydrophobic silica particles provided have an average aspect ratio, AR_{avg}, of ≤1.5 determined by dynamic light scattering according to ISO 22412:2008. More preferably, in the method of making a passivated thin film transistor component for use in a display device of the present invention, the plurality of non-crystalline hydrophobic silica particles provided have an average aspect ratio, AR_{avg}, of ≤1.25 determined by dynamic light scattering according to ISO 22412:2008. Most preferably, in the method of making a passivated thin film transistor component for use in a display device of the present invention, the plurality of non-crystalline hydrophobic silica particles provided have an average aspect ratio, AR_{avg}, of ≤1.1 determined by dynamic light scattering according to ISO 22412:2008.

Preferably, in the method of making a passivated thin film transistor component for use in a display device of the present invention, the plurality of non-crystalline hydrophobic silica particles provided comprise at least two populations of non-crystalline hydrophobic silica particles, wherein each population of non-crystalline hydrophobic silica particles has a different average particles size. More preferably, in the method of making a passivated thin film transistor component for use in a display device of the present invention, the plurality of non-crystalline hydrophobic silica particles provided comprise a first population of non-crystalline hydrophobic silica particles and a second population of non-crystalline hydrophobic silica particles; wherein the first population of non-crystalline hydrophobic silica particles is prepared from a first plurality of hydrophilic silica particles and wherein the second population of non-crystalline hydrophobic silica particles is prepared from a second plurality of hydrophilic silica particles; wherein the first population of non-crystalline hydrophobic silica particles has an average particle size, PS_{avg-first}; wherein the second population of non-crystalline hydrophobic silica particles has an average particles size. PS_{avg-second}; wherein N_{avg-first}>PS_{avg-second}; and wherein PS_{avg-second}/PS_{avg-first}≤0.4.

Preferably, in the method of making a passivated thin film transistor component for use in a display device of the present invention, the plurality of non-crystalline hydrophobic silica particles comprise 5 to 90 wt % (preferably, 15 to 80 wt %; more preferably, 25 to 75 wt %; most preferably, 50 to 70 wt %) of the barrier film based on the total weight of the barrier film.

Preferably, in the method of making a passivated thin film transistor component for use in a display device of the present invention, the plurality of hydrophilic silica particles provided have a water absorbance of >2% determined according to ASTM E1131. More preferably, in the method of making a passivated thin film transistor component for use in a display device of the present invention, the plurality of hydrophilic silica particles provided are prepared using a Stöber synthesis process. Still more preferably, in the method of making a passivated thin film transistor component for use in a display device of the present invention, the plurality of hydrophilic silica particles provided are prepared using a Stöber synthesis process wherein the silica particles are formed via the hydrolysis of alkyl silicates (e.g., tetraethylorthosilicate) in an aqueous alcohol solution (e.g., a water-ethanol solution) using ammonia as a morphological catalyst. See, e.g, Stöber, et al., Controlled Growth of Monodisperse Silica Spheres in the Micron Size Range, JOURNAL OF COLLOID AND INTERFACE SCIENCE, vol. 26, pp. 62-69 (1968).

Preferably, in the method of making a passivated thin film transistor component for use in a display device of the present invention, the water provided is at least one of deionized and distilled to limit incidental impurities. More preferably, in the method of making a passivated thin film transistor component for use in a display device of the present invention, the water provided is deionized and distilled to limit incidental impurities.

Preferably, in the method of making a passivated thin film transistor component for use in a display device of the present invention, the aldose provided is an aldohexose. More preferably, in the method of making a passivated thin film transistor component for use in a display device of the present invention, the aldose provided is an aldohexose, wherein the aldohexose is selected from the group consisting of D-allose, D-altrose, D-glucose, D-mannose, D-gulose, D-idose, D-galactose, D-talose and mixtures thereof. Still more preferably, in the method of making a. passivated thin film transistor component for use in a display device of the present invention, the aldose provided is an aldohexose; wherein the aldohexose is selected from the group consisting of D-glucose, D-galactose, D-mannose and mixtures thereof. Most preferably, in the method of making a passivated thin film transistor component for use in a display device of the present invention, the aldose provided is an aldohexose; wherein the aldose is D-glucose.

Preferably, in the method of making a passivated thin film transistor component for use in a display device of the present invention, the plurality of hydrophilic silica particles are dispersed in the water using well known techniques to form the silica water dispersion. More preferably, in the method of making a passivated thin film transistor component for use in a display device of the present invention, the plurality of hydrophilic silica particles are dispersed in the water using sonication.

Preferably, in the method of making a passivated thin film transistor component for use in a display device of the present invention, the aldose provided is dissolved in the silica water dispersion using well known techniques to form the combination. More preferably, in the method of making a passivated thin film transistor component for use in a display device of the present invention, the aldose is dissolved in the silica water dispersion using sonication to form the combination.

Preferably, in the method of making a passivated thin film transistor component for use in a display device of the present invention, the combination is concentrated using well known techniques to form the viscous syrup. More preferably, in the method of making a passivated thin film transistor component for use in a display device of the present invention, the combination is concentrated using decanting and evaporative techniques to form the viscous syrup. Most preferably, in the method of making a passivated thin film transistor component for use in a display device of the present invention, the combination is concentrated by decanting and rotary evaporating to form the viscous syrup.

Preferably, in the method of making a passivated thin film transistor component for use in a display device of the present invention, the viscous syrup is heated in an inert atmosphere at 500 to 625° C., for 4 to 6 hours to form the char. More preferably, in the method of making a passivated thin film transistor component for use in a display device of the present invention, the viscous syrup is heated in an inert atmosphere at 500 to 625° C. for 4 to 6 hours to form the char; wherein the inert atmosphere is selected from the group selected from a nitrogen atmosphere, an argon atmosphere and a mixture thereof. Still more preferably, in the method of making a passivated thin film transistor component for use in a display device of the present invention, the viscous syrup is heated in an inert atmosphere at 500 to 625° C. for 4 to 6 hours to form the char; wherein the inert atmosphere is selected from the group selected from a nitrogen atmosphere and an argon atmosphere. Most preferably, in the method of making a passivated thin film transistor component for use in a display device of the present invention, the viscous syrup is heated in an inert atmosphere at 500 to 625° C. for 4 to 6 hours to form the char; wherein the inert atmosphere is a nitrogen atmosphere.

Preferably, in the method of making a passivated thin film transistor component for use in a display device of the present invention, the char is comminuted using well known techniques to form the powder. More preferably, in the method of making a passivated thin film transistor component for use in a display device of the present invention, the char is comminuted by at least one of crushing, pulverizing, milling and grinding to form the powder. Most preferably, in the method of making a passivated thin film transistor component for use in a display device of the present invention, the char is comminuted by crushing to form the powder.

Preferably, in the method of making a passivated thin film transistor component for use in a display device of the present invention, the powder in an oxygen containing atmosphere at >650 to 900° C. for 1 to 2 hours to form the plurality of non-crystalline hydrophobic silica particles. More preferably, in the method of making a passivated thin film transistor component for use in a display device of the present invention, the powder in an oxygen containing atmosphere at >650 to 900° C. for 1 to 2 hours to form the plurality of non-crystalline hydrophobic silica particles; wherein the oxygen containing atmosphere is air.

Preferably, in the method of making a passivated thin film transistor component for use in a display device of the present invention, the film forming matrix material and the plurality of non-crystalline hydrophobic silica particles are combined using well known techniques to form the composite. More preferably, in the method of making a passivated thin film transistor component for use in a display device of the present invention, the film forming matrix material and the plurality of non-crystalline hydrophobic silica particles are combined by at least one of stirring and sonication to form the composite. Most preferably, in the method of making a passivated thin film transistor component for use in a display device of the present invention, the film forming matrix material and the plurality of non-crystalline hydrophobic silica particles are combined by sonication to form the composite.

Preferably, in the method of making a passivated thin film transistor component for use in a display device of the present invention, the composite is applied to the thin film transistor component using well known techniques to form the barrier film thereon, providing the passivated thin film transistor component; wherein the semiconductor is interposed between the barrier film and the substrate. More preferably, in the method of making a passivated thin film transistor component for use in a display device of the present invention, the composite is applied to the thin film transistor component to form the barrier film using a method selected from the group consisting of spin coating, dip coating, roll coating, spray coating, laminating, knife blading and printing. Most preferably, in the method of making a passivated thin film transistor component for use in a display device of the present invention, the composite is applied to the thin film transistor component using spin coating to form the barrier film.

Preferably, in the method of making a passivated thin film transistor component for use in a display device of the present invention, the barrier film has a water vapor transmission rate of ≤10.0 g·mil/m²·day measured at 38° C. and 100% relative humidity according to ASTM F1249. More preferably, in the method of making a passivated thin film transistor component for use in a display device of the present invention, the barrier film has a water vapor transmission rate of <10 (more preferably, ≤7.5; most preferably, ≤5.0) g·mil/m²·day measured at 38° C. and 100% relative humidity according to ASTM F1249. Most preferably, in the method of making a passivated thin film transistor component for use in a display device of the present invention, the barrier film has a water vapor transmission rate of ≤5 g·mil/m²·day measured at 38° C. and 100% relative humidity according to ASTM F1249.

Preferably, in the method of making a passivated thin film transistor component for use in a display device of the present invention, the barrier film is a transparent barrier film. More preferably, in the method of making a passivated thin film transistor component for use in a display device of the present invention, the barrier film is a transparent barrier film; wherein the transparent barrier film has a transmission, T_{Trans}, of ≥50% (more preferably, T_{Trans} is ≥80%; most preferably, T_{Trans} ≥90%) as measured according to ASTM D1003-11e1. Most preferably, in the method of making a passivated thin film transistor component for use in a display device of the present invention, the barrier film is a transparent barrier film; wherein the transparent barrier film has a transmission, T_{Trans}, of ≥90% as measured according to ASTM D1003-11e1.

Preferably, in the method of making a passivated thin film transistor component for use in a display device of the present invention, the barrier film is a transparent barrier film; wherein the transparent barrier film has a transmission, T_{Trans}, of ≥50% as measured according to ASTM D1003-11e1 and a water vapor transmission rate of ≤10.0 g·mil/m²·day measured at 38° C. and 100% relative humidity according to ASTM F1249. More preferably, in the method of making a passivated thin film transistor component for use in a display device of the present invention, the barrier film is a transparent barrier film; wherein the transparent barrier film has a transmission, T_{Trans}, of ≥80% as measured according to ASTM D1003-11e1 and a water vapor transmission rate of <10 g·mil/m²·day measured at 38° C. and 100% relative humidity according to ASTM F1249. Most preferably, in the method of making a passivated thin film transistor component for use in a display device of the present invention, the barrier film is a transparent barrier film; wherein the transparent barrier film has a transmission, T_{Trans}, of ≥90% as measured according to ASTM D1003-11e1 and a water vapor transmission rate of ≤5 g·mil/m²·day measured at 38° C. and 100% relative humidity according to ASTM F1249.

Preferably, in the method of making a passivated thin film transistor component for use in a display device of the present invention, the barrier film has a thickness of 10 nm to 25 microns (preferably, 75 nm to 10 microns; more preferably; 250 nm to 5 micros; most preferably, 700 nm to 2.5 microns).

Preferably, in the method of making a passivated thin film transistor component for use in a display device of the present invention, further comprises: providing an additive; wherein the additive is combined with the film forming matrix material and the plurality of non-crystalline hydrophobic silica particles to form the composite. More preferably, in the method of making a passivated thin film transistor component for use in a display device of the present invention, further comprises: providing an additive, wherein the additive is selected from the group consisting of accelerators, antioxidants, refractive index modifiers (e.g., nonreactive diluents, viscosity modifiers (e.g., a thickener), reinforcing materials, fillers, surfactants (e.g., wetting agents, dispersants), refractive index modifiers, nonreactive diluents, matting agents, coloring agents (e.g., pigments, dyes), stabilizers, chelating agents, leveling agents, viscosity modifiers, thermal regulating agents, optical dispersants (e.g., light scattering particles) and mixtures thereof; wherein the additive is combined with the film forming matrix material and the plurality of non-crystalline hydrophobic silica, particles to form the composite. Most preferably, in the method of making a passivated thin film transistor component fbr use in a display device of the present invention, further comprises: providing an additive, wherein the additive is selected from the group consisting of accelerators, antioxidants (e.g., benzophenone, triazine, benzotriazole, phosphites, derivatives and mixtures thereof, refractive index modifiers (e.g., TiO₂), nonreactive diluents, viscosity modifiers (e.g., a thickener), reinforcing materials, fillers, surfactants (e.g., wetting agents, dispersants), refractive index modifiers, nonreactive diluents, matting agents, coloring agents (e.g., pigments, dyes), stabilizers, chelating agents, leveling agents, viscosity modifiers, thermal regulating agents, optical dispersants (e.g., light scattering particles) and mixtures thereof; wherein the additive is combined with the film forming matrix material and the plurality of non-crystalline hydrophobic silica particles to form the composite; and, wherein the additive comprises 0.1 to 10 wt % (more preferably, 0.1 to 5 wt %) of the barrier layer based on total weight of the barrier layer.

Preferably, in the method of making a passivated thin film transistor component for use in a display device of the present invention, further comprises: providing an organic solvent; wherein the organic solvent is combined with the film. forming matrix material and the plurality of non-crystalline hydrophobic silica particles to form the composite. More preferably, in the method of making a passivated thin film transistor component for use in a display device of the present invention, further comprises: providing an organic solvent, wherein the organic solvent is selected from the group consisting of terpineol, dipropylene glycol methyl ether acetate, dipropylene glycol monomethyl ether, propylene glycol n-propyl ether, dipropylene glycol n-propyl ether, cyclohexanone, butyl carbitol, propylene glycol monomethyl ether acetate, xylene and mixtures thereof; and, wherein the organic solvent is combined with the film forming matrix material and the plurality of non-crystalline hydrophobic silica particles to form the composite. Still more preferably, in the method of making a passivated thin film transistor component for use in a display device of the present invention, further comprises: providing an organic solvent, wherein the organic solvent is selected from the group consisting of terpineol, dipropylene glycol methyl ether acetate, propylene glycol monomethyl ether acetate and mixtures thereof; and, wherein the organic solvent is combined with the film forming matrix material and the plurality of non-crystalline hydrophobic silica particles to form the composite. Most preferably, in the method of making a passivated thin film transistor component for use in a display device of the present invention, further comprises: providing an organic solvent, wherein the organic solvent is propylene glycol monomethyl ether acetate; and, wherein the organic solvent is combined with the film forming matrix material and the plurality of non-crystalline hydrophobic silica particles to form the composite.

Preferably, in the method of making a passivated thin film transistor component for use in a display device of the present invention, further comprises: baking the composite after applying the composite to the surface of the substrate to remove any residual organic solvent. More preferably, in the method of making a passivated thin film transistor component for use in a display device of the present invention, further comprises: baking the composite at an elevated temperature (e.g., 70 to 340° C.) for at least 10 seconds to 5 minutes after applying the composite to the surface of the substrate to remove any residual or organic solvent.

Preferably, in the method of making a passivated thin film transistor component for use in a display device of the present invention, further comprises: annealing of the barrier film by any known annealing technique, for example, thermal annealing, thermal gradient annealing and solvent vapor annealing. More preferably, in the method of making a passivated thin film transistor component for use in a display device of the present invention, further comprises: annealing the barrier film by a thermal annealing technique. Still more preferably, in the method of making a passivated thin film transistor component for use in a display device of the present invention, further comprises: annealing the barrier film by heating at a temperature of 200 to 340° C. (more preferably 200 to 300° C.; most preferably 225 to 300° C.) for a period of 0.5 minute to 2 days (more preferably 0.5 minute to 2 hours; still more preferably 0.5 minute to 0.5 hour; most preferably 0.5 minute to 5 minutes). Most preferably, in the method of making a passivated thin film transistor component for use in a display device of the present invention, further comprises: annealing the barrier film in an oxygen free atmosphere (i.e., [O₂]<5 ppm).

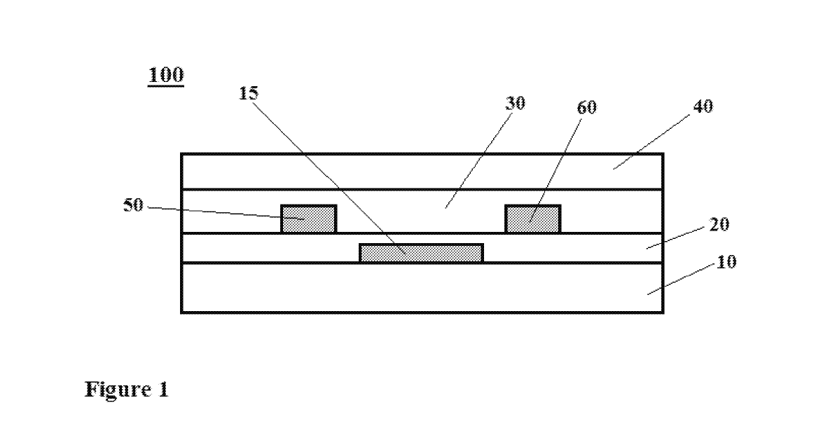

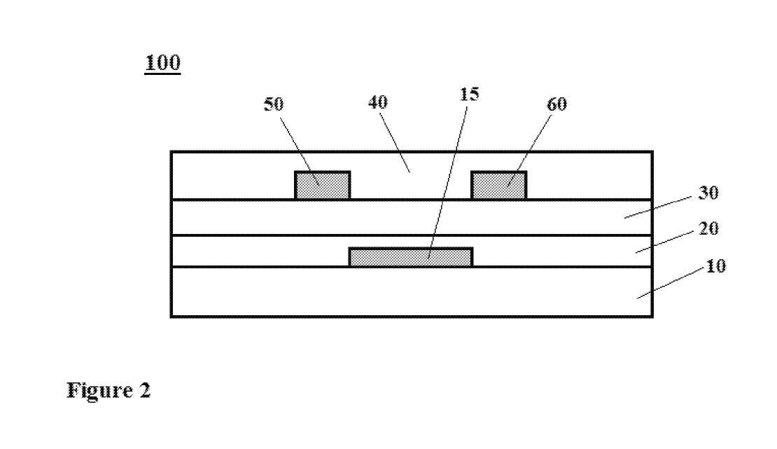

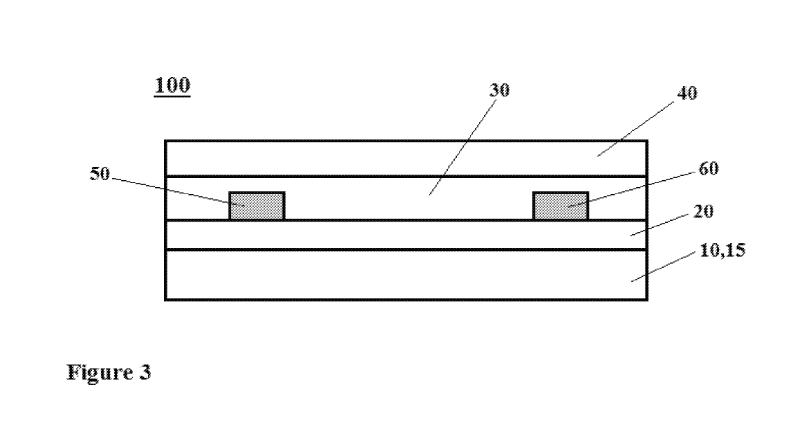

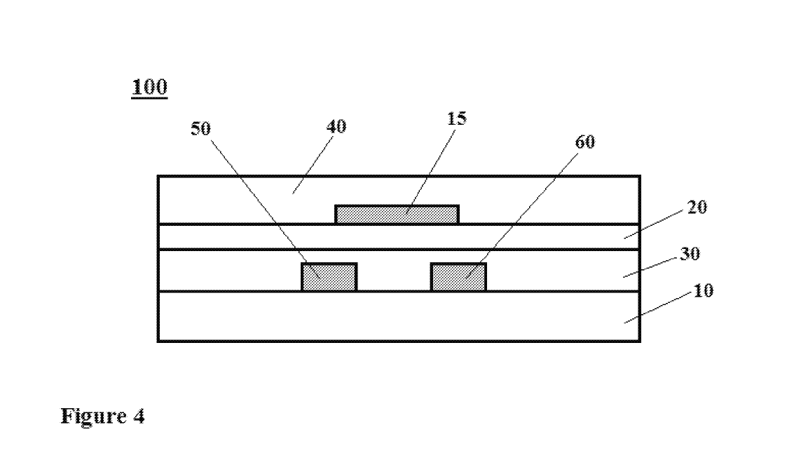

Passivated thin film transistor components prepared according to the method of the present invention can be provided in a variety of configurations. See for example FIGS. 1-4 where different passivated thin film transistor component (100) configurations are depicted comprising a substrate (10), a gate electrode (15), a gate dielectric (20), a semiconductor (30), a barrier layer (40), a source electrode (50) and a drain electrode (60). Note that in some configurations such as the one depicted in FIG. 3, a single material can function as both the substrate (10) and the gate electrode (15).

Some embodiments of the present invention will) v be described in detail in the following Examples.

### EXAMPLES 1-5

### Preparation of Plurality of Hydrophilic Silica Particles

A plurality of hydrophilic silica particles was prepared in each of Examples 1-5 using the following procedure. Deionized water and an aqueous ammonia solution (0.5 molar) in the amounts noted in TABLE 1 were weighed into a 250 mL beaker with a stir bar. The contents of the beaker were allowed to stir for a minute before adding to the beaker either a solution of tetraethylorthosilicate and ethanol (Examples 1-2) or as noted in TABLE 1 to the beaker. The beaker was then sealed with plastic film and the contents were allowed to stir for the reaction time noted in TABLE 1. The contents of the beaker were then centrifuged. The supernatant was removed and the solid sediment was smashed with a lab spoon. The product plurality of hydrophilic silica particles was then triple washed with water and then dried in an oven at 150 to 200° C. for 5 hours. The average particle size of the product plurality of hydrophilic silica particles was then determined by dynamic light scattering according to ISO 22412:2008. The average particle size for the product plurality of hydrophilic silica particles prepared in each of Examples 1-5 is reported in TABLE 1

TABLE 1

| | | 0.5M | | | | | |
|---|---|---|---|---|---|---|---|
| | | Aqueous | TEOS - Ethanol Solution | | | | |
| | DI | NH₃ | 1M | | | Stir | Avg. |
| | water | Solution | solution | TEOS | Ethanol | Time | PS |
| Ex # | (g) | (g) | (mL) | (g) | (g) | (hr) | (nm) |
| 1 | 1.05 | 3.41 | 20 | — | — | 5.5 | 60.4 |
| 2 | 1.05 | 3.41 | 50 | — | — | 6.0 | 66.8 |
| 3 | 1.05 | 3.41 | — | 21.2 | 57.2 | 24 | 84.7 |
| 4 | 6.45 | 3.41 | — | 21.2 | 53.0 | 24 | 182.6 |
| 5 | 2.09 | 6.81 | — | 42.3 | 114 | 24 | 79.6 |

### EXAMPLE 6

### Preparation of Plurality of Non-Crystalline Hydrophobic Silica Particles

A plurality of non-crystalline hydrophobic silica particles was prepared from a plurality of hydrophilic silica particles prepared according to Example 4 using the following procedure. A sample of the plurality of hydrophilic silica particles (1.8 g) prepared according to Example 4 was dispersed with sonication into 100 mL of deionized water to form a dispersion. To the dispersion was then added a glucose (28 g) with sonication to form a combination. The combination was then concentrated in a rotary evaporator to form a viscous syrup. The viscous syrup was then heated in a tube furnace at 600° C. for 5 hours under a nitrogen atmosphere to provide a black foam like material. The black foam like material was then ground with agate mortar and then heated at 800° C. for 1.5 hours under air in a muffle furnace to produce the plurality of non-crystalline hydrophobic silica particles. The plurality of non-crystalline hydrophobic silica particles had a density of 2.63 g/cm³, a water solubility of 1.1 wt % and a weight loss of 0.04 wt % at 300° C. for 1 hour.

### EXAMPLE 7

### Preparation of Polyalkoxysiloxane (PAOS) Film Forming Matrix Material

A polyalkoxysiloxane (PAOS) film forming matrix material was prepared according to the following procedure. In a 1 L three-neCk round-bottom flask equipped with mechanical stirrer and a 30 cm dephlegmator connected with a distillation bridge, tetraethyl orthosilicate (104 g, 0.5 mol) was mixed with acetic anhydride (51 g, 0.5 mol) and titanium trimethylsiloxide (0.3 g) under argon atmosphere. Under intensive stirring the mixture was heated to 135° C. The ethyl acetate generated from reaction of the flask contents was continuously distilled off. Heating was continued until the distillation of ethyl acetate stopped. Afterwards, the product polyalkoxysiloxane (PAOS) film forming matrix material was cooled down to room temperature and dried in vacuum for 5 hours. Complete removal of volatile compounds was achieved using a vacuum at 150° C. Providing a propylene glycol monomethyl ether acetate organic solvent. Adding the product polyalkoxysiloxane (PROS) film forming matrix material to the propylene glycol monomethyl ether acetate to give a 20 wt % solution of the polyalkoxysiloxane in the organic solvent.

### EXAMPLE 8

### Preparation of Polyalkoxysiloxane Copolymer (PAOS-Ph) Film Forming Matrix Material

A polyalkoxysiloxane copolymer (PAOS-Ph) formed from tetraethyl orthosilicate and phenyltrimethoxysilane film forming matrix material was prepared according to the following procedure. In a 1 L three-neck round-bottom flask equipped with mechanical stirrer and a 30 cm dephlegmator connected with a distillation bridge, phenyltrimethoxysilane (16.34 g, 0.082 mol) and tetraethyl orthosilicate (153.54 g, 0.738 mol) was mixed with acetic anhydride (20.91 g, 0.205 mol) and titanium trimethyisiloxide (0.15 g) under argon atmosphere. Under intensive stirring the mixture was heated to 135° C. The ethyl acetate generated from reaction of the flask contents was continuously distilled off. Heating was continued until the distillation of ethyl acetate stopped. Afterward, the product polyalkoxysiloxane copolymer (PROS-Ph) was cooled down to room temperature and dried in vacuum for 5 hours. Complete removal of volatile compounds was achieved using a vacuum at 150° C. Providing a propylene glycol monomethyl ether acetate organic solvent. Adding the product polyalkoxysiloxane copolymer (PAOS-Ph) film forming matrix material to the propylene glycol monomethyl ether acetate to give a 20 wt % solution of the polyalkoxysiloxane copolymer in the organic solvent.

### COMPARATIVE EXAMPLES C1-C2 AND EXAMPLES 9-10

### Barrier Film Preparation

Barrier films were formed on a polyimide film (DuPont Kapton® polyimide film). The polyimide film was cut into round pieces with a diameter of 10 cm which were then adhered to a silicon wafer using double sided tape. The exposed polyimide film surface was then cleaned with a clean room wipe and isopropyl alcohol followed by blow drying. In each of Comparative Examples C1-C2 a composite was formed by adding a plurality of hydrophilic silica particles (Ludox® HS-40 colloidal silica available from Sigma-Aldrich Co. LLC) to the product of Example 7 and 8, respectively, wherein the volume fraction of the silica particles in the composites formed was 60%. In each of Examples 9-10 a composite was formed by adding a plurality of non-crystalline hydrophobic silica particles prepared according to Example 6 to the product of Example 7 and 8, respectively, wherein the volume fraction of the silica particles in the composites formed was 60%. The composites were then filtered with a 0.20 μm PTFE syringe filter, drop cast and blade coated onto the exposed polyimide film surface. The barrier film coated polyimide film substrate was then baked on a hotplate at 240° C. for 2 hr. The barrier film coated polyimide film substrate was then peeled from the silicon wafer for further testing. The thickness of the barrier film was detected by cross-sectional SEM. The water vapor transmission rate (WVTR) through the barrier film was determined with MOCON according to ASTM F1249. The results are reported in TABLE 2.

TABLE 2

| | | WVTR |
|---|---|---|
| Barrier Film | Thickness (μm) | ((g · mil)/(m² · day)) |
| untreated polyimide | — | 92 |
| film | | |
| Comparative Ex. C1 | 2.2 | 45.1 |
| Comparative Ex. C2 | 1.8 | 8.4 |
| Ex. 9 | 0.75 | 5.5 |
| Ex. 10 | 0.74 | 4.6 |

### EXAMPLES 11-12

### Preparation of Plurality of Non-Crystalline Hydrophobic Silica Particles

A plurality of non-crystalline hydrophobic silica particles was prepared from a plurality of hydrophilic silica particles prepared according to Example 5 using the following procedure. In each of Examples 11-12, a sample of the plurality of hydrophilic silica particles (1.8 g) prepared according to Example 5 was dispersed with sonication into 100 mL of deionized water to form a dispersion. To the dispersions was then added a glucose in the amount noted in TABLE 3 with sonication to form combinations. The combinations were then concentrated in a rotary evaporator to form viscous syrups. The viscous syrups were then heated in a tube furnace at 600° C. for 5 hours under a nitrogen atmosphere to provide a foam like material. The foam like material was then ground with agate mortar and then heated at 800° C. for 1.5 hours under air in a. muffle furnace to produce the plurality of non-crystalline hydrophobic silica particles.

### EXAMPLES 13-16

### Particle Size and Distribution Analysis

Pluralities of non-crystalline hydrophobic silica particles formed according to Examples 11-12 were then dispersed in organic solvents as identified in TABLE 3 to form dispersions. The average particle size and polydispersity index for the plurality of non-crystalline hydrophobic silica particles were measured y dynamic light scattering according to ISO 22412.2008 using a Malvern Instruments Zetasizer. The results are provided in TABLE 3.

TABLE 3

| | Plurality of | | Average | |
|---|---|---|---|---|
| | non-crystalline | | Particle | Polydispersity |
| | hydrophobic | | Size | Index |
| Ex. | silica particles | Solvent | PS_{avg} (nm) | PdI |
| 13 | Ex. 11 | Ethanol | 138 | 0.192 |
| 14 | Ex. 11 | Acetone | 86 | 0.195 |
| 15 | Ex. 12 | Ethanol | 146 | 0.192 |
| 16 | Ex. 12 | Acetone | 115 | 0.163 |

We claim:

1. A method of making a passivated thin film transistor component for use in a display device, comprising:
providing a thin film transistor component, comprising: a substrate, at least one electrode, a dielectric and a semiconductor;
providing a film forming matrix material; and,
providing a plurality of non-crystalline hydrophobic silica particles having an average particle size, PS_{avg}, of 5 to 120 nm and a water absorbance of <2% determined according to ASTM E1131, wherein the plurality of non-crystalline hydrophobic silica particles are prepared by:
providing a plurality of hydrophilic silica particles;
providing a water;
providing an aldose;
dispersing the plurality of hydrophilic silica particles in the water to form a silica water dispersion;
dissolving the aldose in the silica water dispersion to form a combination;
concentrating the combination to form a viscous syrup;
heating the viscous syrup in an inert atmosphere at 500 to 625° C. for 4 to 6 hours to form a char;
comminuting the char to form a powder;
heating the powder in an oxygen containing atmosphere at >650 to 900° C. for 1 to 2 hours to form the plurality of non-crystalline hydrophobic silica particles;
combining the film forming matrix material and the plurality of non-crystalline hydrophobic silica particles to form a composite; and,
applying the composite to the thin film transistor component to form a barrier film thereon, providing the passivated thin film transistor component; wherein the semiconductor is interposed between the barrier film and the substrate;
wherein the barrier film has a water vapor transmission rate of ≤10.0 g·mil/m²·day measured at 38° C. and 100% relative humidity according to ASTM F1249.

2. The method of claim 1, wherein the film forming matrix material provided is a polysiloxane.

3. The method of claim 2, wherein the polysiloxane provided has an average compositional formula:
(R³SiO_{3/2})ₐ(SiO_{4/2})_{b}
wherein each R³ is independently selected from a C₆₋₁₀ aryl group and a C₇₋₂₀ alkylaryl group; wherein each R⁷ and R⁹ is independently selected from a hydrogen atom, a C₁₋₁₀ alkyl group, a C₇₋₁₀ arylalkyl group, a C₇₋₁₀ alkylaryl group and a C₆₋₁₀ aryl group;
wherein 0≤a≤0.5;
wherein 0.5≤b≤1;
wherein a+b=1;
wherein the polysiloxane comprises, as initial components:
(i) T units having a formula R³Si(OR⁷)₃; and,
(ii) Q units having a formula Si(OR⁹)₄.

4. The method of claim 3, wherein R³ is a C₆ aryl group; wherein R⁷ is a C₁ alkyl group; and wherein R⁹ is a C₂ alkyl group.

5. The method of claim 1, wherein the plurality of non-crystalline hydrophobic silica particles have an average particle size, PS_{avg}, of 5 to 120 nm; an average aspect ratio, AR_{avg}, of ≤1.5 and a polydispersity index, PdI, of ≤0.275 determined by dynamic light scattering according to ISO 22412:2008.

6. The method of claim 1, wherein the plurality of hydrophilic silica particles provided are prepared using a Stöber synthesis process.

7. The method of claim 1, wherein the aldose provided is an aldohexose.

8. The method of claim 1, further comprising:
providing an organic solvent; and,
wherein the organic solvent is combined with the film forming matrix material and the plurality of non-crystalline hydrophobic silica particles to form the composite.

9. The method of claim 1, further comprising:
providing an additive;
wherein the additive is combined with the film forming matrix material and the plurality of non-crystalline hydrophobic silica particles to form the composite.

10. A passivated thin film transistor component for use in a display device made according to the method of claim 1.
